(19) United States
(12) Patent Application Publication
(10) Pub. No.: US 2024/0266295 A1
(43) Pub. Date: Aug. 8, 2024

(54) ELECTRONIC PACKAGE MODULE AND METHOD FOR FABRICATION OF THE SAME

(71) Applicant: USI Science and Technology (Shenzhen) Co., Ltd., Guangdong Province (CN)

(72) Inventor: LI-CHENG SHEN, Guangdong Province (CN)

(21) Appl. No.: 18/336,041

(22) Filed: Jun. 16, 2023

(30) Foreign Application Priority Data
Feb. 8, 2023 (CN) 202310146775.9

(51) Int. Cl. H01L 23/538; H01L 21/56; H01L 23/31; H01L 23/373; H01L 23/498; H01L 25/065

(52) U.S. Cl. CPC H01L 23/5385; H01L 21/56; H01L 23/3121; H01L 23/3736; H01L 23/49816; H01L 25/0655

(57) ABSTRACT

An electronic package module and the method for fabrication of the same are provided. The method includes providing a circuit substrate with a first surface. An interposer frame and at least one first electronic component are disposed on the first surface. Subsequently, a first molding layer encapsulating the first electronic component and the interposer frame is formed on the first surface. A shielding material is disposed on the first molding layer, and thus the shielding material covers the interposer frame while the opening of the shielding material overlaps the electronic component. With the shielding material as the mask, a heat conductive solder is deposited on the first molding layer. After removing the shielding material, the interposer frame is connected to a main board. Therefore, the heat dissipation of the electronic component toward the main board accelerates due to the heat conductive solder.

### RELATED APPLICATIONS

This application claims priority to China application Serial Number 202310146775.9, filed Feb. 8, 2023, which is herein incorporated by reference in its entirety.

### BACKGROUND

### Technical Field

The present disclosure relates to an electronic package module. More particular, the present disclosure relates to the electronic package module with heat conductive solder and the method for fabrication of the same.

### Description of Related Art

Double sided surface mount technology (SMT) is to dispose the electronic components on two opposite surfaces of a circuit substrate, and to electronically connect the circuit substrate to a main board through a frame board. The electronic components are disposed on the circuit substrate, and thus, a double sided package structure is formed. Although this double sided package structure can increase the number of the disposed electronic components, the heat produced by the inner electronic components should be conducted to the surfaces of the package and directly dissipate by heat convection of the air, or should be conducted to the main board through the frame board.

However, one side of the double sided package structure is connected to the main board, so that the heat from the electric components near to the main board is difficult to be dissipated by heat convection of the air. Therefore, the heat dissipation rate is reduced, and the electronic components may be affected badly. Especially, the electronic components near to the main board may lead to serious problem of heat accumulation.

### SUMMARY

Accordingly, the disclosure is to provide an electronic package module and the method for fabrication of the same, thereby improving the rate of heat dissipation.

At least one embodiment of the disclosure provides a method for fabricating an electronic package module, including providing a circuit substrate including a first surface; disposing an interposer frame and at least one first electronic component on the first surface, and the interposer frame includes an interface far away from the circuit substrate; forming a first molding layer on the first surface, and the first molding layer encapsulates the first electronic component and the interposer frame; disposing a shielding material on the first molding layer, this shielding material covers the interposer frame, and has at least one opening and the opening overlaps the first electronic component; depositing a heat conductive solder on the first molding layer with the shielding material as a mask, and the heat conductive solder does not directly contact the first electronic component; removing the shielding material after depositing the heat conductive solder; and connecting the interposer frame to a main board after removing the shielding material, and the interface of the interposer faces to the main board.

At least one embodiment of the disclosure provides an electronic package module. The electronic package module includes a circuit substrate having a first surface and a second surface; a first electronic component disposed on the first surface; an interposer frame disposed on the first surface and electrically connecting the circuit substrate; a first molding layer encapsulating the first electronic component and the interposer frame; and a heat conductive solder covering the first molding layer and the first electronic component. The first molding layer is located between the first electronic component and the heat conductive solder, and the first electronic component does not directly contact the heat conductive solder.

According to the aforementioned embodiments, a heat conductive solder is disposed on the side of the electronic package module facing to the main board, and on the region overlapping the electronic components. Since the heat conductive solder is located between the package module and the main board, the heat conductive rate transferring from the electronic components to the main board may be increased, thereby improving the heat dissipation rate of the electronic package module.

### BRIEF DESCRIPTION OF THE DRAWINGS

To illustrate more clearly the aforementioned and the other features, merits, and embodiments of the present disclosure, the description of the accompanying figures are as follows:

FIG. 1A to FIG. 1F illustrate cross-sectional views of a method for fabricating an electronic package module in accordance with at least one embodiment of the present disclosure.

FIG. 2 illustrates a top view of a shielding material in accordance with one embodiment of the present disclosure.

FIG. 3 illustrates a local top view of a method for fabricating an electronic package module in accordance with the embodiment of the present disclosure of FIG. 1E.

FIG. 4 illustrates a local top view of a method for fabricating an electronic package module in accordance with another embodiment of the present disclosure.

FIG. 5 illustrates a cross-sectional view of an electronic package in accordance with another embodiment of the present disclosure.

FIG. 6A to FIG. 6C illustrate cross-sectional views of a method for fabricating an electronic package module in accordance with another embodiment of the present disclosure.

FIG. 7 illustrates a cross-sectional view of an electronic package in accordance with another embodiment of the present disclosure.

### DETAILED DESCRIPTION

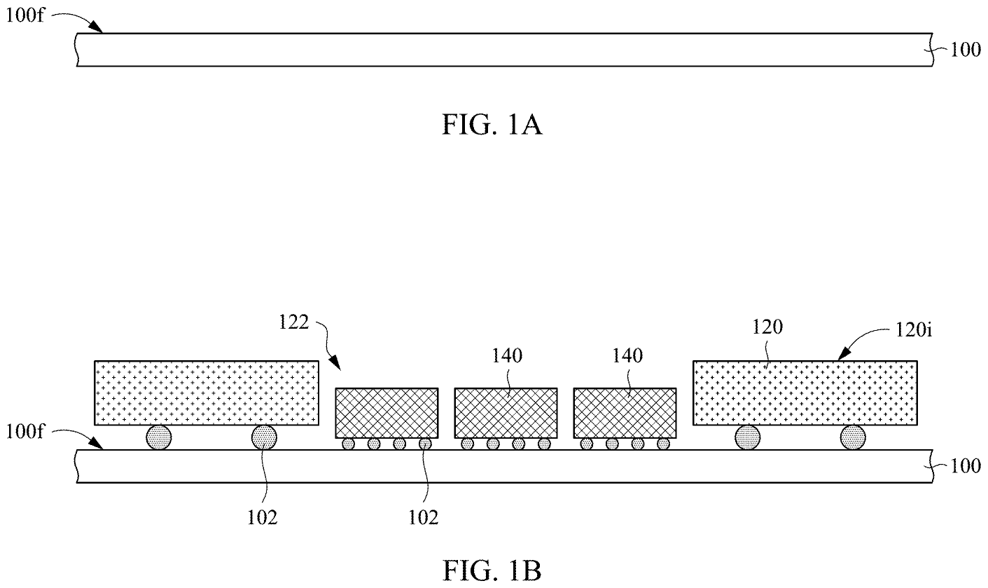

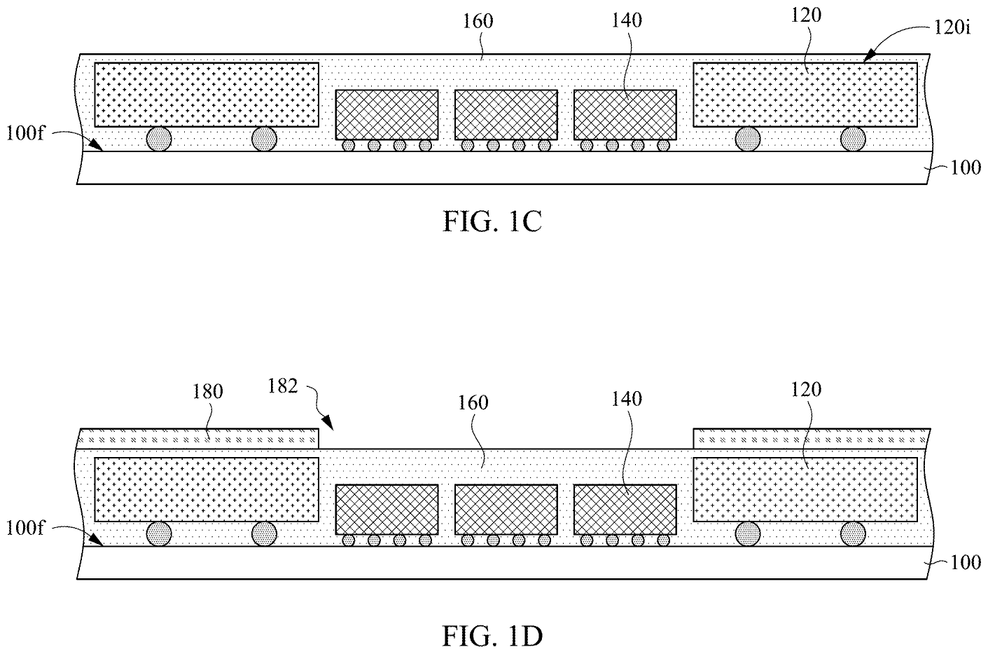

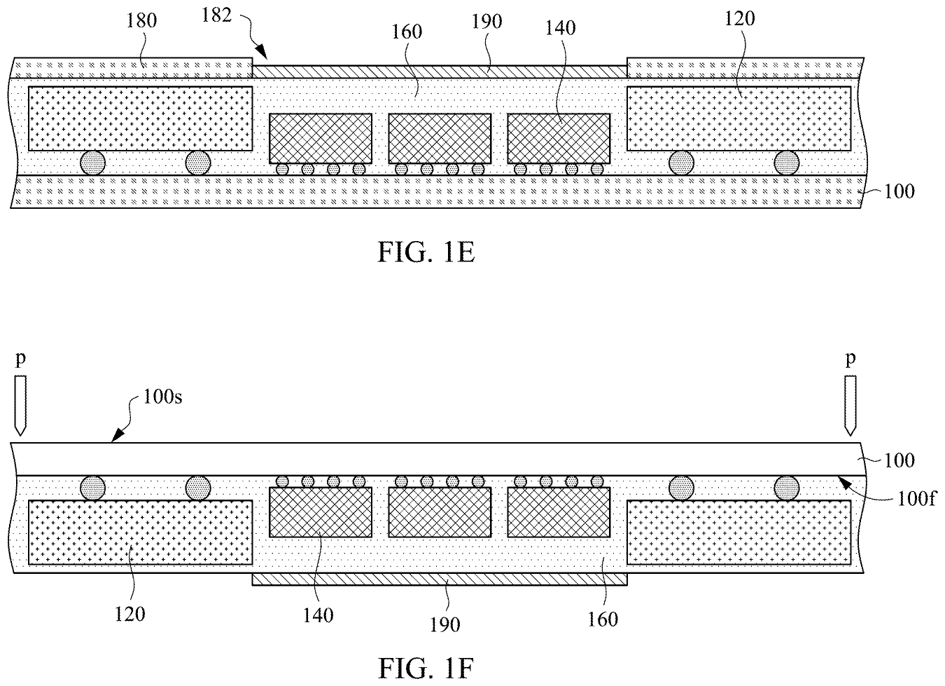

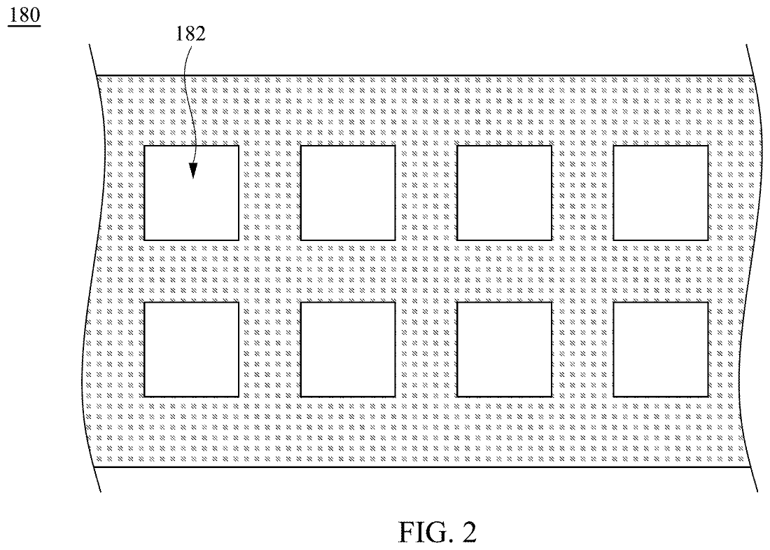

FIG. 1A to FIG. 1F illustrate sequent steps of the method for fabricating an electronic package module in accordance with at least one embodiment of present disclosure. Referring to FIG. 1A, firstly, the circuit substrate 100 which includes the surface 100f is provided. Afterwards, the interposer frame 120 and at least one electronic component 140 is disposed on the surface 100f of the circuit substrate 100 as shown in FIG. 1B. Although the figures of this embodiment illustrates three electronic components 140, the number of the electronic components 140 is not limited to three but one and above in the present disclosure.

In some embodiments, the circuit substrate 100 may further include at least one solder mask (not shown), and the solder mask can cover the surface 100f of the circuit substrate 100 while a plurality of pads (not shown) exposed on the surface 100f. The electronic components 140 are soldered and mounted on the circuit substrate 100 by the plurality of solders 102 via these pads, so that the electronic components 140 are electrically connected to the circuit substrate 100. The solders 102 may be solder balls, copper pillars or other connecting structures for electrically connection. Furthermore, the electronic components 140 may be electrically connected to the circuit substrate 100 with wire-bonding in other embodiments. The electronic components 140 may be packaged as a chip or unpackaged as a die.

Referring to FIG. 1B, the interposer frame 120 includes the interface 120i which is on the side far away from the circuit substrate 100, that is, the interface 120i backs to the surface 100f of the circuit substrate 100. In this embodiment, the number of the interposer frame 120 is one, and the interposer frame 120 includes at least one opening 122 where the electronic components 140 are disposed. However, the number of the interposer frame 120 may be one and above, and each of the interposer frame 120 may include one and above openings 122 (for example, one opening 122) in other embodiments.

In the same way for connecting the electronic components 140 to the circuit substrate 100, the interposer frame 120 is electrically connected to the circuit substrate 100 by the plurality of solders 102 via the pads exposed on the circuit substrate 100 (not shown). It is worth mentioning, although the interface 120i of the interposer frame 120 is above the top side of the electronic components 140, the disclosure is not limited by this embodiment. In other embodiments, the interface 120i of the interposer frame 120 may be below or flush with the top side of the electronic components 140.

Referring to FIG. 1C, the molding layer 160 is formed on the surface 100f after the interposer frame 120 and the electronic components 140 are disposed on the circuit substrate 100, so that the molding layer 160 encapsulates the electronic components 140 and the interposer frame 120. The material of the molding layer 160 may include organic resin (such as epoxy resin) or other isolation material, or similarity thereof. In this embodiment, the molding layer 160 encapsulates the electronic components 140 and the interposer frame 120 completely. However, in other embodiments, a part of the interface 120i of the interposer frame 120 may be exposed from the molding layer 160. In other word, the interposer frame 120 may be partially covered by the molding layer 160.

Afterward, as shown in FIG. 1D, the shielding material 180 is disposed on the molding layer 160, so that the shielding material 180 covers the interposer frame 120. Since the interface 120i is not exposed from the molding layer 160, the shielding material 180 does not directly contact the interposer frame 120 in the embodiment. However, the shielding material 180 may directly contact the interposer frame 120 in other embodiments.

FIG. 2 illustrates a local top view of the shielding material 180. Referring to FIG. 1D and FIG. 2, the shielding material 180 has at least one opening 182, and the opening 182 overlaps the electronic components 140 to uncover the electronic components 140 from the shielding material 180. The shielding material 180 may be a steel stencil or other alloy stencil, but the shielding material 180 in present disclosure is not limited to a metal stencil. For example, the shielding material 180 may be a ceramic plate or a tape which includes polymers (such as polyimide tape).

As FIG. 2 shown, the shielding material 180 may include the plurality of openings 182. The number and the position of the openings 182 are configured in accordance with the openings 122 of the interposer frame 120 since the openings 182 should overlap the electronic components 140 while the electronic components 140 are disposed in the openings 122 of the interposer frame 120. In addition, although the shielding material 180 covers the whole interposer frame 120 (even beyond the whole interposer frame 120) in this embodiment, the present disclosure is not limited by this embodiment. In other embodiments, the shielding material 180 may cover the interposer frame 120 partially. In other words, the size and the shape of the openings 182 of the shielding material 180 may be different from the size and the shape of the openings 122 of the interposer frame 120.

Referring to FIG. 1E, the heat conductive solder 190 is deposited on the molding layer 160 with the shielding material 180 as the mask. It is noted that the heat conductive solder 190 does not directly contact the electronic components 140 since the molding layer 160 exists in in-between. In the embodiment, the heat conductive solder 190 may be deposited on the molding layer 160 by sputtering, stencil printing or other similar method. The material of the heat conductive solder 190 may include solder metals such as copper, tin or the alloy thereof.

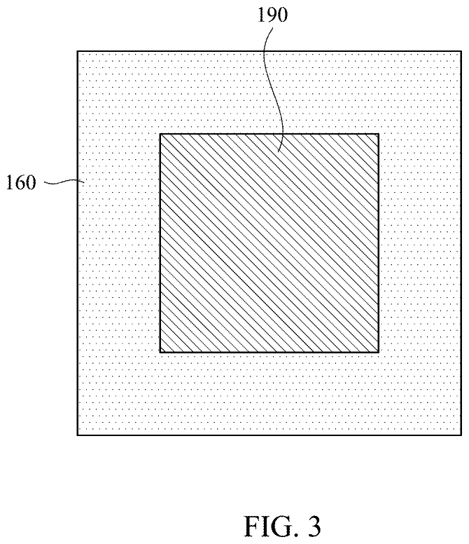

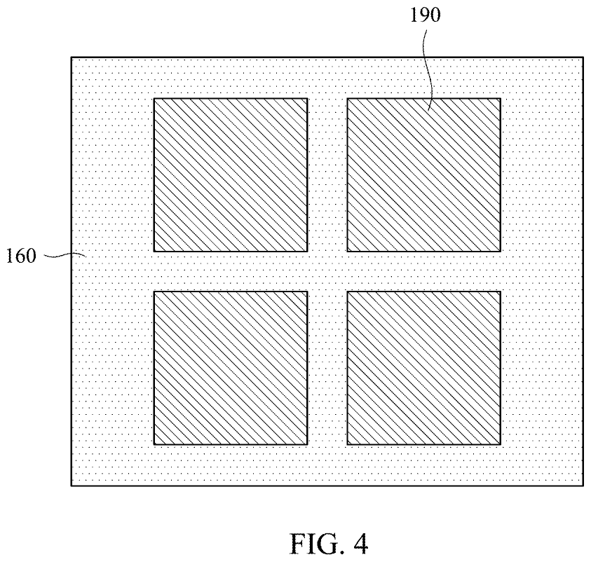

As shown in FIG. 3 in which the shielding material 180 is omitted, the heat conductive solder 190 is deposited in each of the openings 182 as one single block in this embodiment. It is worth mentioning, the heat conductive solder 190 in each of the openings 182 (not denoted) may include a plurality of blocks in some embodiments. Referring to FIG. 4 illustrating another embodiment in which the shielding material 180 is omitted. For example, the plurality of blocks of the heat conductive solder 190 (not denoted) separated from each other are included in one single opening 182 (not denoted). As a result, the uniformity of the thickness of the heat conductive solder 190 may increase, so that the heat conductive solder 190 is prevented from flowing unevenly during the soldering.

The shielding material 180 is removed after the heat conductive solder 190 is deposited. In this embodiment, the circuit substrate 100, the molding layer 160 and the interposer frame 120 are cut with, for example, machine cutting, laser cutting or ion beam cutting after the shielding material 180 is removed. Referring to FIG. 1F, the cutting device p cut the circuit substrate 100 from the surface 100s and along with the normal direction of the circuit substrate 100, so that a plurality of isolated electronic package elements are formed. The cutting device p may be the cutting tool, the laser beam or the ion beam.

It should be noted, although the cutting is conducted after the heat conductive solder 190 is formed, the cutting is not limited to be in this sequence. In particular, the circuit substrate 100, the molding layer 160 and the interposer frame 120 may be cut before the shielding material 180 is removed.

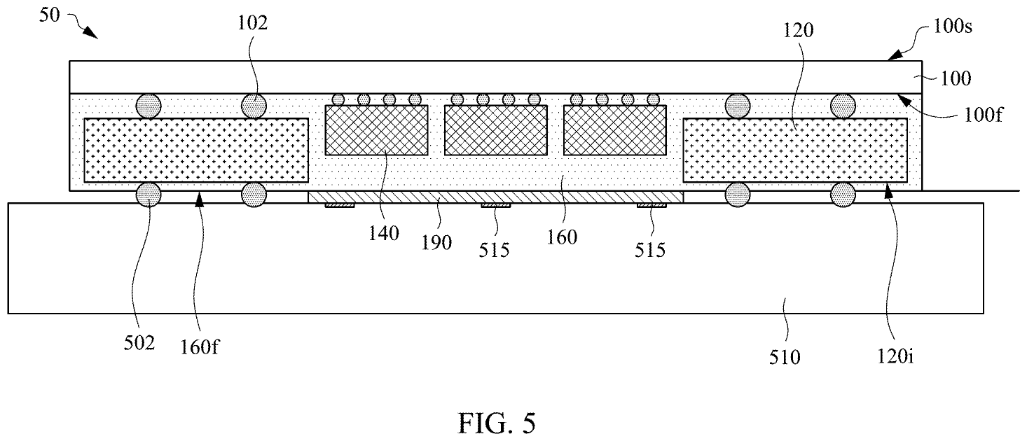

Referring to FIG. 5, the interposer frame 120 is connected to the main board 510 after the shielding material 180 is removed and the electronic package elements are formed by cutting. The interface 120i of the interposer frame 120 faces to the main board 510 in the connection, thus, the surface 100f of the circuit substrate 100 faces to the main board 510. In this step, the plurality of solder materials 502 are disposed on the interface 120i of the interposer frame 120. The material of the solder materials 502 may be the same as the material of the solders 102. Afterwards, these solder materials 502 are connected to the main board 510.

Furthermore, the main board 510 is soldered with the heat conductive solder 190 on the molding layer 160, so that the main board 510 is connected to the molding layer 160, thereby attaching the electronic package element to the main board 510. The heat conductive solder 190 may be grounded via the main board 510 since the heat conductive solder 190 directly contacts the main board 510.

Referring to FIG. 5, the structure of the electronic package module in at least on embodiment is disclosed. The electronic package module 50 of this embodiment includes the circuit substrate 100, the interposer frame 120, the electronic components 140, the molding layer 160 and the heat conductive solder 190. The circuit substrate 100 has the surface 100f and the surface 100s opposite to the surface 100f, and the electronic components 140 are mounted on the surface 100f and electrically connected to the circuit substrate 100 via the plurality of solders 102. The solders 102 may be solder balls, copper pillars or other connecting structures for electrically connection. Although the figures of this embodiment illustrate three electronic components 140 apiece, the number of the electronic components 140 is not limited to three but one and above in the present disclosure. In addition, the interposer frame 120 is on the surface 100f and is electrically connected to the circuit substrate 100 via the plurality of solders 102.

Referring to FIG. 5, the molding layer 160 encapsulates the electronic components 140 and the interposer frame 120. The material of the molding layer 160 may include organic resin (such as epoxy resin) or other isolation material, or similarity thereof. In this embodiment, the molding layer 160 encapsulates the electronic components 140 completely but exposes a part of the interposer frame 120. In other words, the interposer frame 120 may be partially covered by the molding layer 160.

The heat conductive solder 190 is on the molding layer 160 and overlaps the molding layer 160 and the electronic components 140. As shown in FIG. 5, the molding layer 160 is between the electronic components 140 and the heat conductive solder 190 while the electronic components 140 do not directly contact the heat conductive solder 190 in this embodiment. In other words, the electronic components 140 and the heat conductive solder 190 are separated by the molding layer 160 without any direct contact between each other. In addition, the molding layer 160 has the surface 160f far away from the circuit substrate 100, and the heat conductive solder 190 is above the surface 160f. However, the disclosure is not limited by this embodiment. In other embodiments, the heat conductive solder 190 may be below or flush with the surface 160f.

The electronic package module 50 in the embodiment includes the main board 510 which connected to the heat conductive solder 190. The interposer frame 120 and the electronic components 140 are between the circuit substrate 100 and the main board 510, while the interposer frame 120 is electrically connected to the main board 510 via the plurality of solder materials 502 on the interposer frame 120. The material of the solder materials 502 may be the same as the material of the solders 102. The main board 510 includes the pads 515, and the heat conductive solder 190 is connected to the main board 510 via these pads 515 in the embodiment. It is worth mentioning that at least one of the pads 515 may be electrically connected to the grounding circuit in order to ground the heat conductive solder 190.

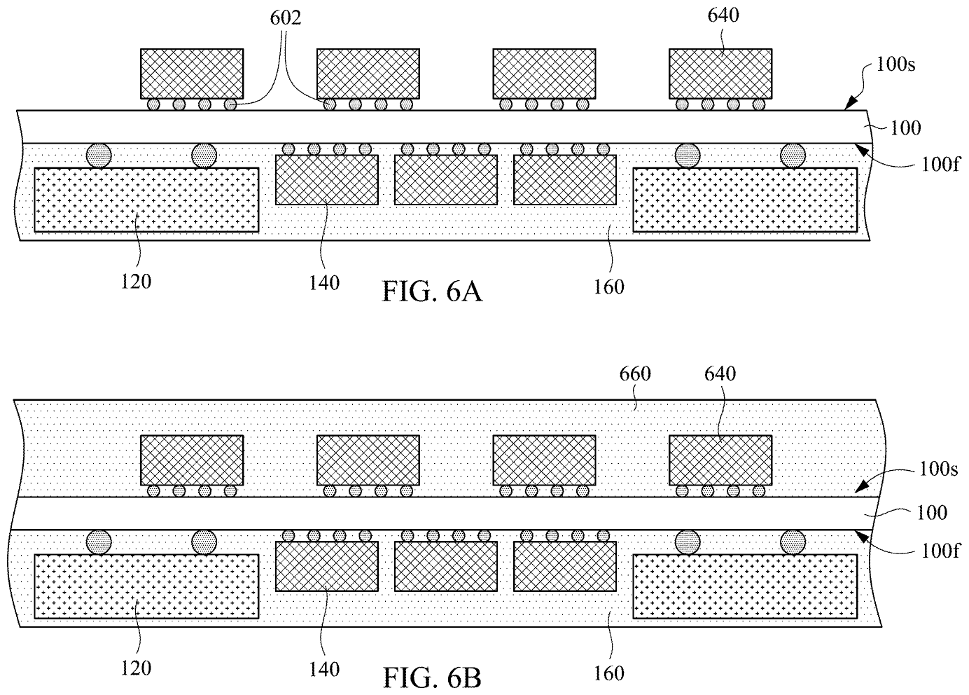

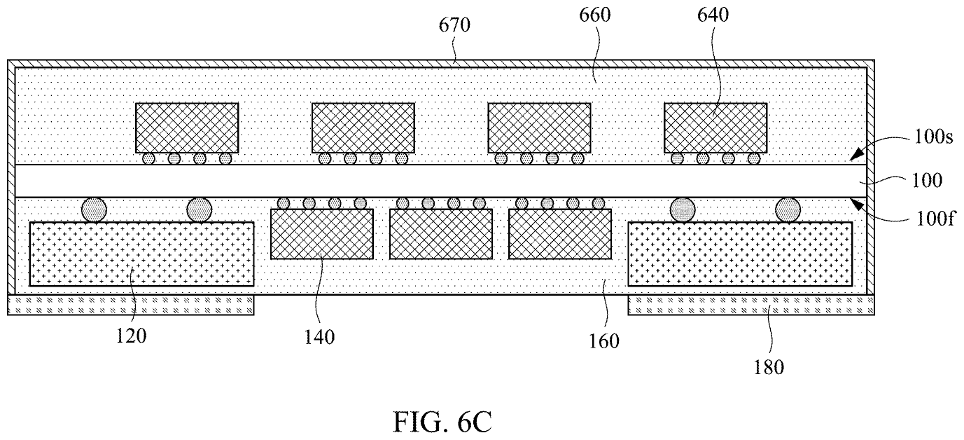

FIG. 6A to FIG. 6B illustrate a cross-sectional view of a method for fabricating an electronic package module in accordance with another embodiment of the present disclosure, and the step of FIG. 6A can follow up the step of FIG. 1C. The steps before FIG. 6A of this embodiment are the same as the FIG. 1A to FIG. 1C, and thus, the descriptions of those steps are not repeated hereof.

Referring to FIG. 6A, the electronic components 640 are disposed on the other surface 100s of the circuit substrate 100 after the molding layer 160 is formed. The types of the electronic components 640 may be the same as the types of the electronic components 140. The surface 100f and the surface 100s are on the opposite sides of the circuit substrate 100, and the electronic components 640 may be electrically connected to the circuit substrate 100 via the plurality of solders 602 which may be the same as the solders 102. Although the figures of this embodiment illustrate four electronic components 140 apiece, the number of the electronic components 140 is not limited to four but one and above (e.g. one electronic component 140) in the present disclosure.

Referring to FIG. 6B, the molding layer 660 is formed to encapsulate the electronic components 640 on the surface 100s after the electronic components 640 are disposed and mounted. The material of the molding layer 660 may include organic resin (such as epoxy resin) or other isolation material, or similarity thereof.

The following steps of this embodiment after FIG. 6B are similar to the steps of the aforementioned embodiment illustrated in FIG. 1D to FIG. 1F. The difference between this embodiment and the aforementioned embodiment is that the electrical conductive layer 670 may be deposited on the molding layer 660 after the shielding material 180 is disposed, as shown in FIG. 6C. Since the electrical conductive layer 670 completely covers the electronic components 640, the electrical conductive layer 670 may electromagnetically shield the electronic components 640. The material of the electrical conductive layer 670 may include metals (such as copper, nickel or alloys), conductive adhesive or other materials and may be deposited with spin coating, sputtering, chemical plating or other similar methods. It should be noted that the cutting process should be conducted before the electrical conductive layer 670 is deposited, so that the electrical conductive layer 670 can cover the side surfaces of the electronic components 640.

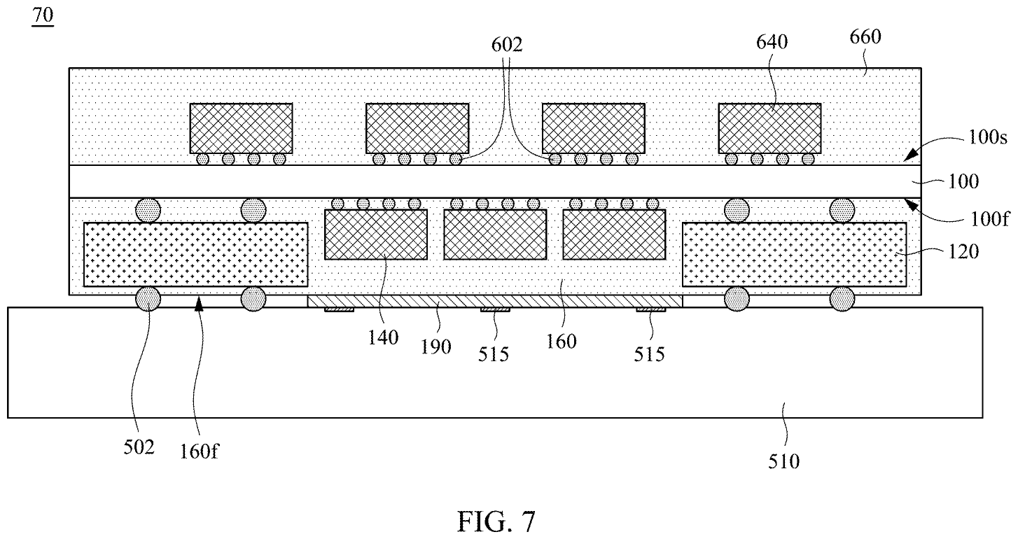

FIG. 7 illustrates the cross-section view of the electronic package module 70 in accordance with another embodiment of present disclosure. The difference between the electronic package module 70 and the electronic package module 50 is that the electronic package module 70 further includes the electronic components 640 and the molding layer 660. Four electronic components 640 are on the surface 100s of the circuit substrate 100 in this embodiment, and the electronic components 640 are electrically connected to the circuit substrate 100 via the plurality of solders 602. However, the number of the electronic components 640 is not limited by the embodiment while the number of the electronic components 640 may be one and above.

Moreover, other devices such as antennas may be disposed on the surface 100s instead of the electronic components 640, and the electrical conductive layer 670 in FIG. 6C may be excluded from the electronic package module 70. The molding layer 660 completely covers the electronic components 640 in this embodiment. However, the molding layer 660 may partially cover the electronic components 640 or may cover none of the electronic components 640 in other embodiments.

In conclusion, the heat conductive rate transferring from the electronic components to the main board (that is, the heat transfers from the electronic components along with the direction leaving the circuit substrate) may be increased by disposing the heat conductive solder in the electronic package module, thereby improving the heat dissipation rate of the electronic package module. In addition, the bonding strength between the electronic package elements and the main board may be enhanced since the heat conductive solder is soldered on the main board. Therefore, the reliability of the connection between solders and the main board are increased.

Although the embodiments of the present disclosure have been disclosed as above in the embodiments, they are not intended to limit the embodiments of the present disclosure. Any person having ordinary skill in the art can make various changes and modifications without departing from the spirit and the scope of the embodiments of the present disclosure. Therefore, the protection scope of the embodiments of the present disclosure should be determined according to the scope of the appended claims.

What is claimed is:

1. A method for fabricating an electronic package module, comprising:
providing a circuit substrate comprising a first surface;
disposing an interposer frame and at least one first electronic component on the first surface, wherein the interposer frame comprises an interface far away from the circuit substrate;
forming a first molding layer on the first surface, wherein the first molding layer encapsulates the first electronic component and the interposer frame;
disposing a shielding material on the first molding layer, wherein the shielding material covers the interposer frame, wherein the shielding material has at least one opening, and the opening overlaps the first electronic component;
depositing a heat conductive solder on the first molding layer with the shielding material as a mask, wherein the heat conductive solder does not directly contact the first electronic component;
removing the shielding material after depositing the heat conductive solder; and
connecting the interposer frame to a main board after removing the shielding material, wherein the interface of the interposer faces to the main board.

2. The method of claim 1, wherein connecting the interposer frame to the main board comprising:
disposing a plurality of solder materials on the interface of the interposer frame; and
connecting the plurality of solder materials to the main board.

3. The method of claim 1, further comprising:
soldering the main board with the heat conductive solder, thereby the first molding layer connecting to the main board.

4. The method of claim 1, further comprising:
grounding the heat conductive solder via the main board.

5. The method of claim 1, wherein the circuit substrate, the first molding layer and the interposer frame are cut after removing the shielding material.

6. The method of claim 1, wherein the circuit substrate, the first molding layer and the interposer frame are cut before disposing the shielding material.

7. The method of claim 1, further comprising:
disposing a second electronic component on a second surface of the circuit substrate, wherein the first surface and the second surface are on two opposite sides of the circuit substrate; and
forming a second molding layer on the second surface, wherein the second molding layer encapsulates the second electronic component.

8. The method of claim 7, further comprising:
depositing an electrical conductive layer, wherein the electrical conductive layer completely covers the second electronic component.

9. An electronic package module, comprising:
a circuit substrate having a first surface and a second surface;
a first electronic component disposed on the first surface;
an interposer frame disposed on the first surface and electrically connected to the circuit substrate;
a first molding layer encapsulating the first electronic component and the interposer frame; and
a heat conductive solder covering the first molding layer and the first electronic component, wherein the first molding layer is located between the first electronic component and the heat conductive solder, and the first electronic component does not directly contact the heat conductive solder.

10. The electronic package module of claim 9, further comprising:
a second electronic component disposed on the second surface; and
a second molding layer covering the second electronic component.

11. The electronic package module of claim 9, wherein the first molding layer has a third surface far away from the circuit substrate, and the heat conductive solder protrudes from the third surface.

12. The electronic package module of claim 9, further comprising:
a main board connected to the heat conductive solder, wherein the interposer frame and the first electronic component is located between the circuit substrate and the main board.

13. The electronic package module of claim 12, wherein the main board comprising:
a pad connecting the main board and the heat conductive solder.

14. The electronic package module of claim 12, further comprising:
a plurality of solder materials located on an interface of the interposer frame and connected to the main board.

15. The electronic package module of claim 9, wherein the heat conductive solder comprises a plurality of blocks separated from each other.
